(19) United States
(12) Patent Application Publication
(10) Pub. No.: US 2026/0076260 A1
(43) Pub. Date: Mar. 12, 2026

(54) METHOD OF MANUFACTURING SEMICONDUCTOR PACKAGE

(71) Applicant: Samsung Electronics Co., Ltd., Suwon-si (KR)

(72) Inventors: Taeoh Ha, Suwon-si (KR); Jaemok Jung, Suwon-si (KR); Dongjun Kim, Suwon-si (KR); Jongho Park, Suwon-si (KR); Hyun Yang, Suwon-si (KR); Hyunju Lee, Suwon-si (KR)

(21) Appl. No.: 19/081,445

(22) Filed: Mar. 17, 2025

(30) Foreign Application Priority Data
Sep. 10, 2024 (KR) 10-2024-0123429

(51) Int. Cl. H01L 25/11; H01L 21/48; H01L 21/768; H01L 23/00; H01L 23/498; H01L 23/538

(52) U.S. Cl. CPC H10W 90/00; H10W 20/043; H10W 70/092; H10W 70/611; H10W 70/65; H10W 90/701; H10W 70/60; H10W 90/724

(57) ABSTRACT

A method of manufacturing a semiconductor package includes forming a plurality of redistribution pads including a first pad layer, a second pad layer, and a third pad layer sequentially stacked on a redistribution structure, forming a preliminary seed layer conformally extending on an upper surface of the redistribution structure, and on upper surfaces and side surfaces of the plurality of redistribution pads, forming a metal pillar on the preliminary seed layer, forming surface roughness on the metal pillar, and etching at least a portion of the preliminary seed layer exposed on the side surfaces of the plurality of redistribution pads and the upper surface of the redistribution structure to provide a seed layer between the metal pillar and one of the plurality of redistribution pads thereon.

### CROSS-REFERENCE TO RELATED APPLICATION

This application is based on and claims ranking under 35 U.S. C. § 119 to Korean Patent Application No. 10-2024-0123429 filed on Sep. 10, 2024, in the Korean Intellectual Property office, the disclosure of which is incorporated by reference herein in its entirety.

### BACKGROUND OF THE INVENTION

The inventive concept relates to a method of manufacturing a semiconductor package. More particularly, the inventive concept relates to a method of manufacturing a semiconductor package including a metal pillar.

With the miniaturization and enhancement of performance of semiconductor chips, interest in semiconductor packages with improved rigidity and heat dissipation characteristics and package on package (POP) structures that combine multiple packages may be increasing. It may be desirable to develop semiconductor packages with improved rigidity and heat dissipation characteristics while implementing a package on package (POP) structure including a conductive structure inside the packages.

### SUMMARY OF THE INVENTION

The inventive concept provides a method of manufacturing a semiconductor package including a metal pillar providing mechanical stability.

However, the inventive concepts are not limited to those mentioned above, and other embodiments may be clearly understood by those of ordinary skill in the art from the following descriptions.

Provided below is a method of manufacturing a semiconductor device.

According to an aspect of the inventive concept, there is provided a method of manufacturing a semiconductor package including forming a plurality of redistribution pads including a first pad layer, a second pad layer, and a third pad layer sequentially stacked on a redistribution structure, forming a preliminary seed layer conformally extending on an upper surface of the redistribution structure, and on upper surfaces and side surfaces of the plurality of redistribution pads, forming a metal pillar on the preliminary seed layer, forming surface roughness on the metal pillar, and etching at least a portion of the preliminary seed layer exposed on the side surfaces of the plurality of redistribution pads and the upper surface of the redistribution structure to provide a seed layer between the metal pillar and one of the plurality of redistribution pads thereon.

According to another aspect of the inventive concept, there is provided a method of manufacturing a semiconductor package including forming a plurality of redistribution pads on a redistribution structure, forming a preliminary seed layer conformally extending on an upper surface of the redistribution structure, and on upper surfaces and side surfaces of the redistribution pads, forming metal pillars on the preliminary seed layer, the metal pillars having respective cross-sectional areas less than those of the plurality of redistribution pads, forming surface roughness on side surfaces of the metal pillars, and providing a plurality of seed layers between the plurality of redistribution pads and the metal pillars, by etching the preliminary seed layer to expose the upper surface of the redistribution structure and a portion of the upper surface and side surfaces of the plurality of redistribution pads, wherein the plurality of redistribution pads comprise copper (Cu), nickel (Ni), and gold (Au) sequentially stacked between each of the redistribution structure and an adhesive layer, and the plurality of seed layers comprise titanium (Ti) and Cu sequentially stacked.

According to another aspect of the inventive concept, there is provided a method of manufacturing a semiconductor package including forming a plurality of redistribution pads, respectively including copper (Cu), nickel (Ni), and gold (Au) sequentially stacked on a redistribution structure including a redistribution via and a redistribution line, forming a preliminary seed layer conformally extending on an upper surface of the redistribution structure and on upper surfaces and side surfaces of the plurality of redistribution pads, the preliminary seed layer comprising a first layer comprising titanium (Ti) and a second layer comprising copper (Cu) sequentially stacked, forming a metal pillar having a cross-sectional area less than those of the plurality of redistribution pads on the preliminary seed layer, performing a Czochralski (CZ) process on the metal pillar, removing portions of the preliminary seed layer such that a portion of the preliminary seed layer remains between one of the plurality of redistribution pads and the metal pillar as a seed layer, mounting at least one semiconductor chip on the redistribution structure, and forming a molding layer in a space between the at least one semiconductor chip and the metal pillar.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to embodiments of the present disclosure;

FIGS. 2A and 2B illustrate enlarged cross-sectional views of region EX1 and region EX2 in FIG. 1;

FIG. 3 is a cross-sectional view of a semiconductor package according to embodiments of the present disclosure;

FIG. 4 is a cross-sectional view of a semiconductor package according to embodiments of the present disclosure;

FIGS. 5, 6A, 6B, 6C, 6D, 7, 8, 9, 10, 11, and 12 are cross-sectional views of respective operations of a method of manufacturing a semiconductor package according to embodiments of the present disclosure;

FIGS. 13, 14, 15, and 16 are cross-sectional views of respective operations of a method of manufacturing a semiconductor package according to embodiments of the present disclosure; and

FIG. 17 is a cross-sectional view of a method of manufacturing a semiconductor package according to embodiments of the present disclosure.

### DETAILED DESCRIPTION OF EMBODIMENTS

Hereinafter, embodiments of the inventive concept are described in detail with reference to accompanying diagrams. Identical reference numerals are used for the same constituent devices in the drawings, and duplicate descriptions thereof are omitted.

Because various changes may be applied to the embodiments and the inventive concept may have various embodiments, particular embodiments are illustrated in the diagrams and described in detail. However, this is not intended to limit the inventive concept to particular modes of practice, and it is to be appreciated that all changes, equivalents, and substitutes, which do not depart from the spirit and technical scope of the inventive concept, are encompassed in the inventive concept. In the description of the embodiments, certain detailed explanations of the related art are omitted when it is deemed that they may unnecessarily obscure the essence of the embodiments.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other discontinuities throughout. The term “exposed” may be used to describe relationships between elements and/or certain intermediate processes in fabricating a completed semiconductor device, but may not necessarily require exposure of the particular region, layer, structure or other element in the context of the completed device.

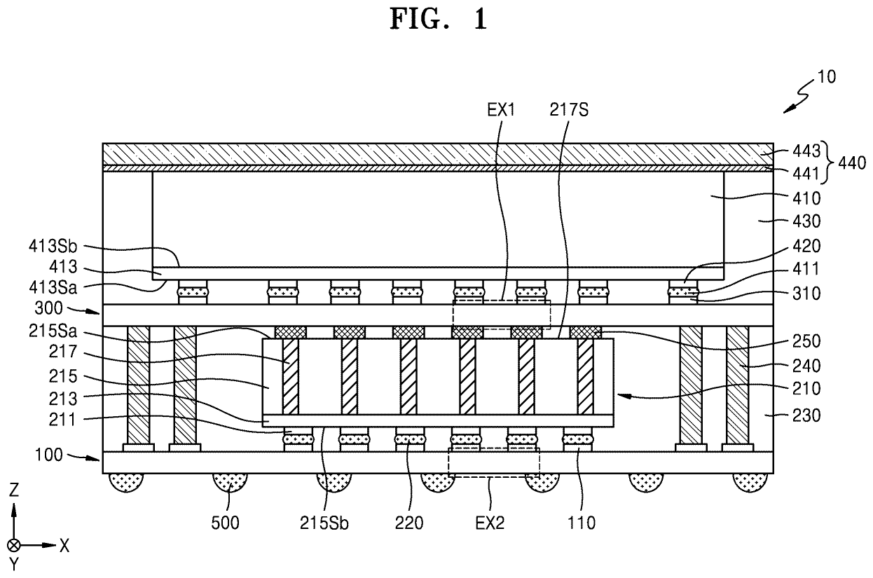

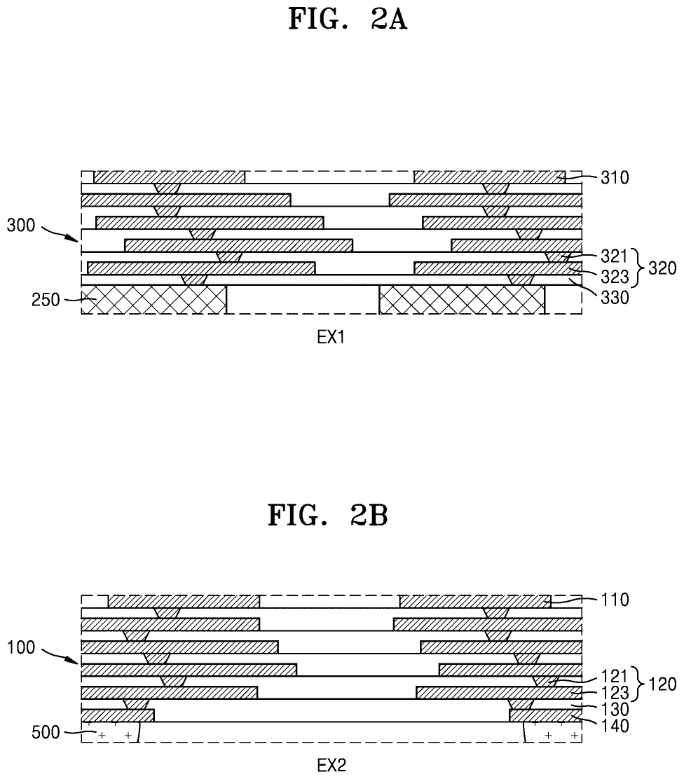

FIG. 1 is a cross-sectional view of a semiconductor package 10 according to an embodiment. FIGS. 2A and 2B illustrate enlarged cross-sectional views of region EX1 and region EX2 in FIG. 1. FIG. 2A is an enlarged cross-sectional view of region EX1 in FIG. 1, and FIG. 2B is an enlarged cross-sectional view of region EX2 in FIG. 1.

Referring to FIG. 1, the semiconductor package 10 may include a first redistribution structure 100, a first semiconductor chip 210, a first molding layer 230, a first connection structure 240, a second redistribution structure 300, a second semiconductor chip 410, a second molding layer 430, and a metal layer 440.

The first redistribution structure 100 may include a substrate on which the first semiconductor chip 210 is mounted. Referring to FIGS. 1 and 2A-2B together, the first redistribution structure 100 may include a first redistribution pattern 120 and a first redistribution insulating layer 130. Hereinafter, unless particularly defined, a direction in parallel with an upper surface of the first redistribution structure 100 may be defined as a horizontal direction (that is, X direction and Y direction), and a direction perpendicular to the upper surface of the first redistribution structure 100 may be defined as a vertical direction (that is, Z direction).

The first redistribution insulating layer 130 may cover the first redistribution pattern 120. The first redistribution insulating layer 130 may include a plurality of insulating layers stacked in the vertical direction or may include a single insulating layer. The first redistribution insulating layer 130 may include, for example, photo imageable dielectric (PID) or photosensitive polyimide (PSPI).

The first redistribution pattern 120 may include a plurality of first redistribution lines 123 extending in the horizontal direction and a plurality of first redistribution vias 121 penetrating at least a portion of the first redistribution insulating layer 130 and extending. The plurality of first redistribution lines 123 may extend in the horizontal direction along at least one of an upper surface and a lower surface of each of the insulating layers constituting the first redistribution insulating layer 130. Some of the plurality of first redistribution lines 123 may be at a different vertical level from some of the rest of the plurality of first redistribution lines 123. The plurality of first redistribution vias 121 may electrically connect the plurality of first redistribution lines 123 at different vertical levels. In an embodiment, a horizontal width of the plurality of first redistribution vias 121 may increase toward the first semiconductor chip 210. The first redistribution pattern 120 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and/or an alloy thereof. The first redistribution pattern 120 may include a plurality of first redistribution pads 110 at an uppermost end. Lower surfaces of the plurality of first redistribution pads 110 may be covered by the first redistribution insulating layer 130.

A plurality of under bump metal (UBM) layers 140 may be arranged at a lowermost end of the first redistribution pattern 120. At least a portion of each of the plurality of UBM layers 140 may be covered by the first redistribution insulating layer 130. For example, an upper surface and sidewalls of each of the plurality of UBM layers 140 may be completely covered by the first redistribution insulating layer 130. The plurality of UBM layers 140 may electrically connect the first redistribution pattern 120 to an external connection terminal 500. The plurality of UBM layers 140 may include a metal, such as Cu, Al, W, Ti, Ta, In, Mo, Mn, Co, Sn, Ni, Mg, Re, Be, Ga, Ru, and/or an alloy thereof. The plurality of UBM layers 140 may further include UBM seed layers (not illustrated). In this case, the UBM seed layer may be formed by performing, for example, a physical vapor deposition process, and the plurality of UBM layers 140 may be formed by using an electroplating process using the UBM seed layer.

Referring to FIG. 1 again, the external connection terminal 500 may be arranged on a lower surface of the first redistribution structure 100. Some of the external connection terminals 500 may be arranged so as not to overlap the first semiconductor chip 210 and the second semiconductor chip 410 in the vertical direction. The external connection terminal 500 may include, for example, solder. The external connection terminal 500 may physically and electrically connect between an external device and the semiconductor package 10.

The first semiconductor chip 210 may be mounted on the first redistribution structure 100. In an embodiment, the first semiconductor chip 210 may include a memory chip or a logic chip. The memory chip may include, for example, a volatile memory chip, such as dynamic random access memory (RAM) (DRAM) and static RAM (SRAM), or a non-volatile memory chip, such as phase-change RAM (PRAM), magneto-resistive RAM (MRAM), ferroelectric RAM (FeRAM), and/or resistive RAM (RRAM). In addition, the logic chip may include, for example, a microprocessor, an analog element, or a digital signal processor. The first semiconductor chip 210 may include a first chip pad 211, a wiring structure 213, a first semiconductor substrate 215, and a through electrode 217.

The first semiconductor substrate 215 may include a Group IV semiconductor such as silicon (Si) and germanium (Ge), a Group IV-IV compound semiconductor such as silicon-germanium (SiGe) and silicon carbide (SiC), or a Group III-V semiconductor such as gallium arsenide (GaAs), indium arsenide (InAs), and indium phosphide (InP). The first semiconductor substrate 215 may include a conductive region, for example, a well doped with impurities. The first semiconductor substrate 215 may have various device isolation structures such as a shallow trench isolation (STI) structure.

The first semiconductor substrate 215 may include a first active surface 215Sa and a first inactive surface 215Sb opposite to the first active surface 215Sa. The first active surface 215Sa of the first semiconductor substrate 215 may correspond to an upper surface of the first semiconductor substrate 215 facing the second redistribution structure 300, and the first inactive surface 215Sb of the first semiconductor substrate 215 may correspond to a lower surface of the first semiconductor substrate 215 facing the first redistribution structure 100.

A first front-end-of-line (FEOL) structure (not illustrated) and a first back-end-of-line (BEOL) structure (not illustrated) may be arranged on the first active surface 215Sa. For example, the first FEOL structure may be arranged on the first active surface 215Sa, and the first BEOL structure may be arranged on the first FEOL structure.

The first FEOL structure may include a plurality of first individual devices of various types. The plurality of individual devices may include various microelectronic devices, for example, a metal-oxide-semiconductor field effect transistor (MOSFET) such as a complementary metal-oxide-semiconductor (CMOS) transistor, an image sensor, such as system large scale integration (LSI) and a CMOS imaging sensor (CIS), a micro electro-mechanical system (MEMS), an active element, a passive element, etc. The plurality of first individual devices may be electrically connected to the conductive region of the first semiconductor substrate 215. Each of the plurality of first individual devices may be electrically separated from other neighboring individual devices by a first insulating layer (not illustrated).

The first BEOL structure may include a first BEOL insulating layer (not illustrated) and a first BEOL pattern (not illustrated) covered by the first BEOL insulating layer. The first BEOL pattern may be electrically connected to the plurality of first individual devices and the conductive region of the first semiconductor substrate 215. The first BEOL pattern may include a metal, such as Cu, Al, W, Ti, Ta, In, Mo, Mn, Co, Sn, Ni, Mg, Re, Be, Ga, Ru, and/or an alloy thereof.

The wiring structure 213 may be arranged on a lower surface of the first semiconductor substrate 215. The wiring structure 213 may include a wiring insulating layer (not illustrated) and a wiring pattern (not illustrated) covered by the wiring insulating layer. The first chip pad 211 may be arranged on a lower surface of the wiring structure 213.

The through electrode 217 may penetrate the first semiconductor substrate 215 and extend in the vertical direction. The through electrode 217 may electrically connect between the wiring structure 213 and the BEOL structure arranged on the first active surface 215Sa. The through electrode 217 may include a conductive plug of a column shape and a conductive barrier layer surrounding a sidewall of the conductive plug. The conductive plug may include, for example, at least one material of Cu, Al, W, Ti, Ta, In, Mo, Mn, Co, Sn, Ni, Mg, Re, Be, Ga, and/or Ru. The conductive barrier layer may include at least one material of Ti, TiN, Ta, TaN, W, WN, Ru, and/or Co. Although FIG. 1 illustrates that the through electrode 217 is included in the first semiconductor chip 210, the inventive concept is not limited thereto. For example, unlike as illustrated in FIG. 1, the first semiconductor chip 210 may not include the through electrode 217, but the second semiconductor chip 410 may include the through electrode 217.

A first connection terminal 220 may be arranged between the first semiconductor chip 210 and the first redistribution structure 100. The first connection terminal 220 may be in contact with the first chip pad 211 of the first semiconductor chip 210 and the first redistribution pad 110 of the first redistribution structure 100 and may physically and electrically connect the first semiconductor chip 210 to the first redistribution structure 100. The first connection terminal 220 may include at least one of solder, tin (Sn), silver (Ag), Cu, and/or aluminum (Al).

The first molding layer 230 may be arranged on the first redistribution structure 100 and may cover at least a portion of the first semiconductor chip 210. The first molding layer 230 may extend along the upper surface, the lower surface, and opposing sidewalls of the first semiconductor chip 210, and may cover the upper surface, the lower surface, and the opposing sidewalls of the first semiconductor chip 210. In some embodiments, the first molding layer 230 may include insulating polymer or epoxy resin. For example, the first molding layer 230 may include epoxy mold compound (EMC).

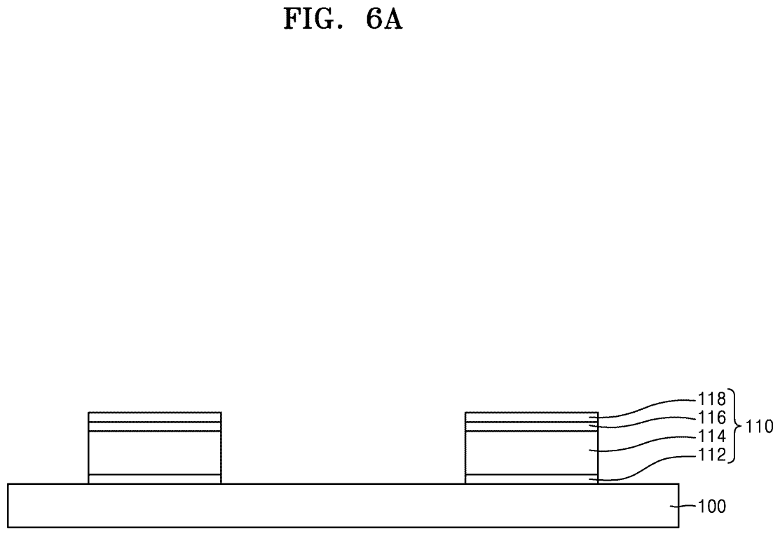

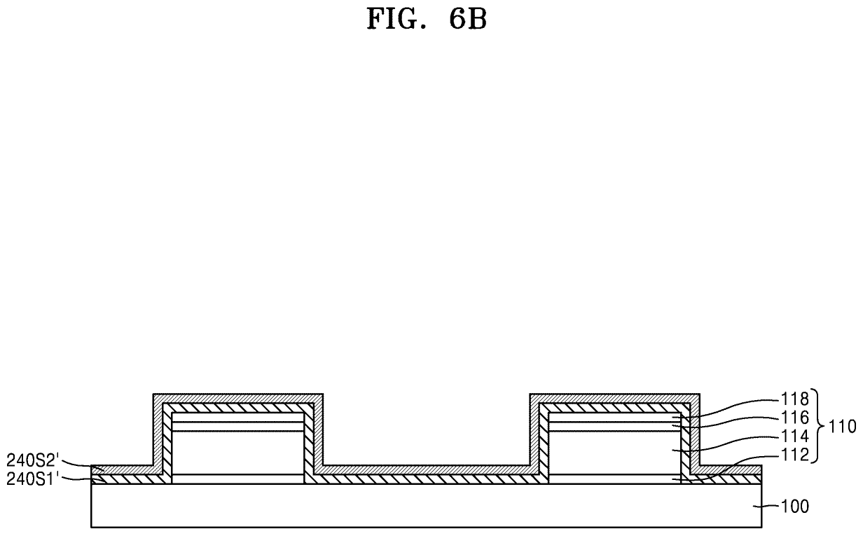

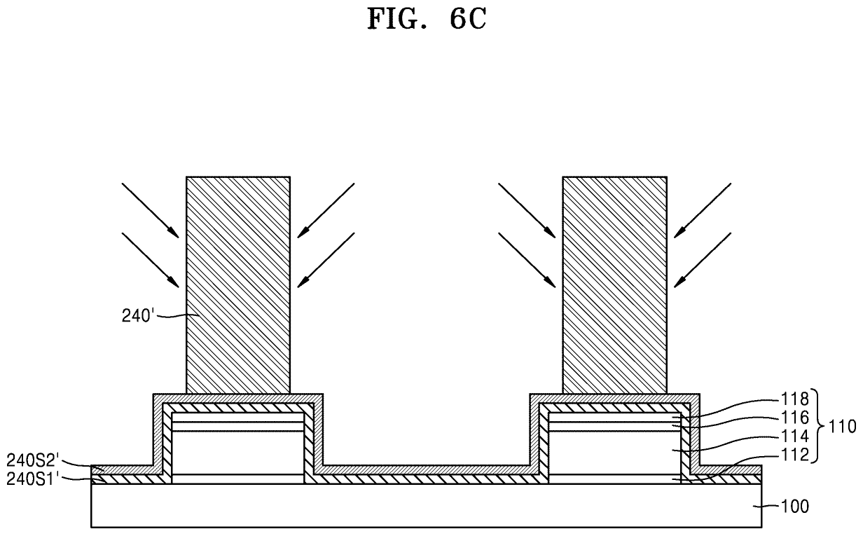

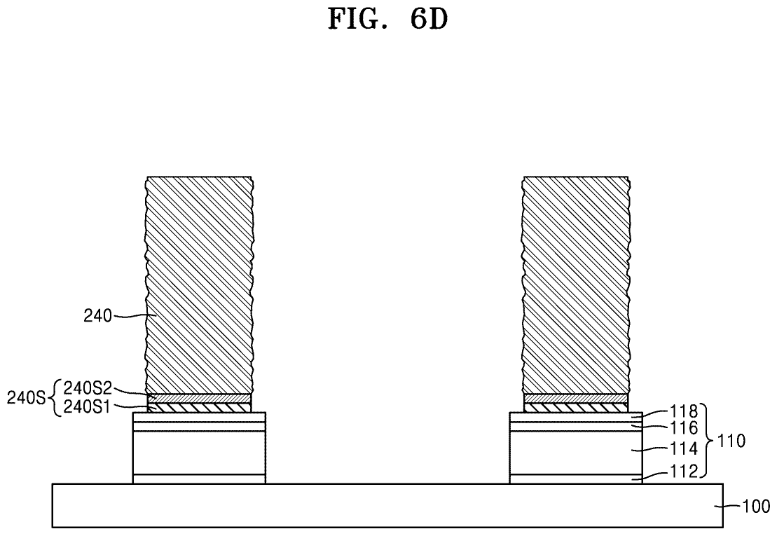

The first connection structure 240 may be arranged on the first redistribution structure 100 and may be connected to the first redistribution pad 110 of the first redistribution structure 100. The first connection structure 240 may be formed on a seed layer 240S formed on the first redistribution structure 100. The first connection structure 240 may penetrate the first molding layer 230 and may extend in the vertical direction. A second redistribution structure 300 may be electrically connected to the first redistribution structure 100 via the first connection structure 240. A detailed description of the first redistribution pad 110, the seed layer 240S, and the first connection structure 240 is given below with reference to FIGS. 6A, 6B, 6C, and 6D.

A second connection structure 250 may be arranged on the first semiconductor chip 210 and may be connected to the through electrode 217 of the first semiconductor chip 210. When the first FEOL structure and the first BEOL structure are arranged on the first active surface 215Sa of the first semiconductor substrate 215, the second connection structure 250 may be connected to the first BEOL structure. The second connection structure 250 may penetrate a portion of the first molding layer 230 and may extend in the vertical direction. An upper surface of the second connection structure 250, an upper surface of the first connection structure 240, and an upper surface of the first molding layer 230 may be coplanar. The first semiconductor chip 210 may be electrically connected to the second redistribution structure 300 via the second connection structure 250. In an embodiment, the second connection structure 250 may include a conductive pillar including Cu. However, the embodiment is not limited thereto, and the second connection structure 250 may also include a conductive bump or a conductive solder.

The second redistribution structure 300 may be arranged on the first molding layer 230. The second redistribution structure 300 may include a substrate on which the second semiconductor chip 410 is mounted. Referring to FIGS. 1 and 2 together, the second redistribution structure 300 may include a second redistribution pattern 320 and a second redistribution insulating layer 330.

The second redistribution insulating layer 330 may cover the second redistribution pattern 320. The second redistribution insulating layer 330 may include a plurality of insulating layers stacked in the vertical direction or may include a single insulating layer. The second redistribution insulating layer 330 may include, for example, PID or PSPI.

The second redistribution pattern 320 may include a plurality of second redistribution lines 323 extending in the horizontal direction, and a plurality of second redistribution vias 321 extending through at least partially the second redistribution insulating layer 330. The plurality of second redistribution lines 323 may extend in the horizontal direction along at least one of an upper surface and a lower surface of each of the insulating layers constituting the second redistribution insulating layer 330. Some of the plurality of second redistribution lines 323 may be at a different vertical level from some of the rest of the plurality of second redistribution lines 323. The plurality of second redistribution vias 321 may electrically connect the plurality of second redistribution lines 323 at different vertical levels. In an embodiment, a horizontal width of the plurality of second redistribution vias 321 may decrease toward the first semiconductor chip 210. The second redistribution pattern 320 may include a metal, such as Cu, Al, W, Ti, Ta, In, Mo, Mn, Co, Sn, Ni, Mg, Re, Be, Ga, Ru, and/or an alloy thereof. The second redistribution pattern 320 may include a plurality of second redistribution pads 310 at an uppermost end. Lower surfaces of the plurality of second redistribution pads 310 may be covered by the second redistribution insulating layer 330.

Referring to FIG. 1 again, the second semiconductor chip 410 may be mounted on the second redistribution structure 300. The second semiconductor chip 410 may include a second chip pad 420 and a second semiconductor substrate 413.

In an embodiment, the second semiconductor chip 410 may include a memory chip or a logic chip. In an embodiment, the first semiconductor chip 210 and the second semiconductor chip 410 may include homogeneous semiconductor chips or heterogeneous semiconductor chips.

In an embodiment, the first semiconductor chip 210 and the second semiconductor chip 410 may include a logic chip. In an embodiment, the first semiconductor chip 210 and the second semiconductor chip 410 may be electrically connected to each other to operate as a single logic chip. For example, the first semiconductor chip 210 may include a physical layer (PHY) chip or a modem chip, the second semiconductor chip 410 may include a central processing unit (CPU) chip or a graphics processing unit (GPU) chip, and the first semiconductor chip 210 and the second semiconductor chip 410 may operate as one logic chip.

The second semiconductor chip 410 may be mounted on the second redistribution structure 300 to overlap the first semiconductor chip 210 in the vertical direction (e.g., the Z direction). In this case, the center of the second semiconductor chip 410 may overlap the center of the first semiconductor chip 210 in the vertical direction. The center of the first semiconductor chip 210 or the second semiconductor chip 410 may refer to a point equidistant from sidewalls of the respective semiconductor chips in the X and/or Y direction.

In an embodiment, a horizontal area of the second semiconductor chip 410 may be greater than a horizontal area of the first semiconductor chip 210. In this case, the horizontal area means an area on a plane perpendicular to the vertical direction (that is, an area on the X-Y plane).

The second semiconductor substrate 413 may include the same material as or a similar material to the first semiconductor substrate 215. The second semiconductor substrate 413 may include a conductive region, for example, a well doped with impurities or a structure doped with impurities. Also, the second semiconductor substrate 413 may have various device isolation structures such as an STI structure.

The second semiconductor substrate 413 may include a second active surface 413Sa and a second inactive surface 413Sb opposite to the second active surface 413Sa. The second active surface 413Sa of the second semiconductor substrate 413 may correspond to a lower surface of the second semiconductor substrate 413 facing the second redistribution structure 300, and the second inactive surface 413Sb of the second semiconductor substrate 413 may correspond to an upper surface of the second semiconductor substrate 413 facing the metal layer 440.

A second FEOL structure (not illustrated) and a second BEOL structure (not illustrated) may be arranged on the second active surface 413Sa. For example, the second FEOL structure may be arranged on the second active surface 413Sa, and the second BEOL structure may be arranged on the second FEOL structure.

The second FEOL structure may include a plurality of second individual devices of various types. The plurality of second individual devices may include various micro-electronic devices, for example, a metal-oxide semiconductor field effect transistor (MOSFET) such as a complementary metal oxide semiconductor (CMOS) transistor, an image sensor, such as system large-scale integration (LSI) and a CMOS image sensor (CIS), a micro-electro mechanical system MEMS, an active device, a passive device, etc. The plurality of second individual devices may be electrically connected to the conductive region of the second semiconductor substrate 413. Each of the plurality of second individual devices may be electrically separated from other neighboring individual devices by a second insulating layer (not illustrated).

The second BEOL structure may include a second BEOL insulating layer (not illustrated) and a second BEOL pattern (not illustrated) covered by the second BEOL insulating layer. The second BEOL pattern may be electrically connected to the plurality of second individual devices and the conductive region of the second semiconductor substrate 413. The second BEOL pattern may include the same material as or a similar material to the first BEOL pattern.

A second connection terminal 411 may be arranged between the second semiconductor chip 410 and the second redistribution structure 300. The second connection terminal 411 may be in contact with the second chip pad 420 of the second semiconductor chip 410 and the second redistribution pad 310 of the second redistribution structure 300 and may physically and electrically connect the second semiconductor chip 410 to the second redistribution structure 300. The second connection terminal 411 may include a material substantially the same as or similar to a material of the first connection terminal 220.

The second molding layer 430 may be arranged on the second redistribution structure 300 and may cover at least a portion of the second semiconductor chip 410. The second molding layer 430 may extend along a lower surface and opposing sidewalls of the second semiconductor chip 410 and may cover the lower surface and the opposing sidewalls of the second semiconductor chip 410. In this case, an upper surface of the second molding layer 430 may be coplanar with the upper surface of the second semiconductor chip 410. In an embodiment, the second molding layer 430 may include insulating polymer or epoxy resin. In an embodiment, the second molding layer 430 and the first molding layer 230 may include different materials.

The metal layer 440 may be arranged on the second semiconductor chip 410 and the second molding layer 430. In an embodiment, the metal layer 440 may completely cover an upper surface of the second semiconductor chip 410 and an upper surface of the second molding layer 430. In an embodiment, the metal layer 440 may include a first metal layer 441 in contact with the upper surface of the second semiconductor chip 410 and the upper surface of the second molding layer 430, and a second metal layer 443 arranged on the first metal layer 441. In an embodiment, the first metal layer 441 may include Ti, and the second metal layer 443 may include Cu.

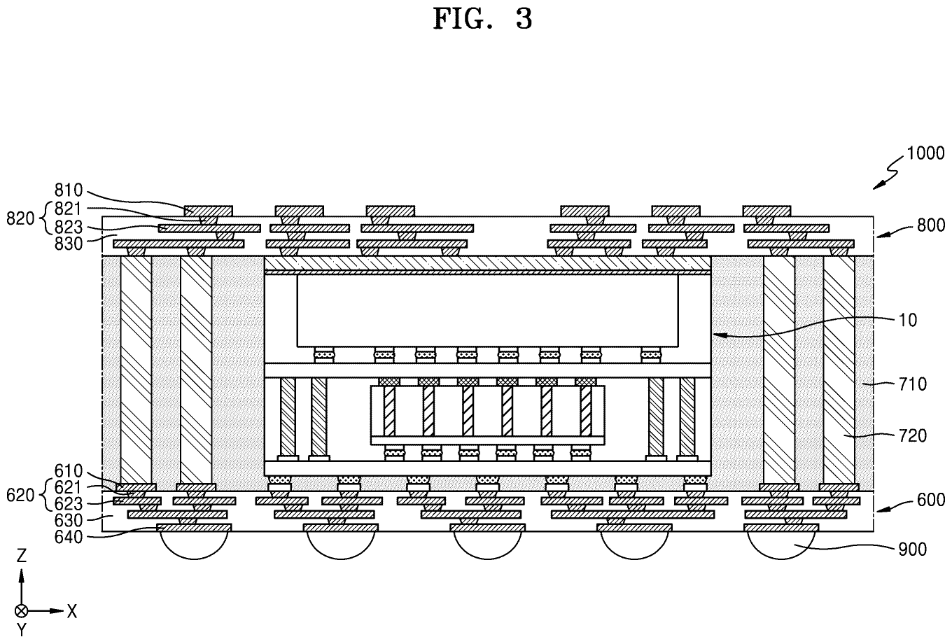

FIG. 3 is a cross-sectional view of a semiconductor package 1000 according to an embodiment.

Referring to FIG. 3, the semiconductor package 1000 may include a lower redistribution structure 600, the semiconductor package 10, a lower molding layer 710, a lower connection structure 720, and an upper redistribution structure 800.

The lower redistribution structure 600 may include a substrate on which the semiconductor package 10 is mounted. The lower redistribution structure 600 may include a lower redistribution pattern 620 and a lower redistribution insulating layer 630.

The lower redistribution insulating layer 630 may cover the lower redistribution pattern 620. The lower redistribution insulating layer 630 may include a plurality of insulating layers stacked in the vertical direction or may include a single insulating layer. The lower redistribution insulating layer 630 may include, for example, PID or PSPI.

The lower redistribution pattern 620 may include a plurality of lower redistribution lines 623 extending in the horizontal direction and a plurality of lower redistribution vias 621 penetrating at least partially the lower redistribution insulating layer 630 and extending. The plurality of lower redistribution lines 623 may extend in the horizontal direction along at least one of an upper surface and a lower surface of each of the insulating layers constituting the lower redistribution insulating layer 630. Some of the plurality of lower redistribution lines 623 may be at a different vertical level from some of the rest of the plurality of lower redistribution lines 623. The plurality of lower redistribution vias 621 may electrically connect the plurality of lower redistribution lines 623 at different vertical levels. In an embodiment, a horizontal width of the plurality of lower redistribution vias 621 may increase toward a sub semiconductor package 10Sa. The lower redistribution pattern 620 may include a metal, such as Cu, Al, W, Ti, Ta, In, Mo, Mn, Co, Sn, Ni, Mg, Re, Be, Ga, and Ru, or an alloy thereof. The lower redistribution pattern 620 may include a plurality of lower redistribution pads 610 at the uppermost end. Lower surfaces of the plurality of lower redistribution pads 610 may be covered by the lower redistribution insulating layer 630.

A plurality of lower UBM layers 640 may be arranged at the lowermost end of the lower redistribution pattern 620. At least a portion of each of the plurality of lower UBM layers 640 may be covered by the lower redistribution insulating layer 630. For example, the lower surface and sidewalls of each of the plurality of lower UBM layers 640 may be completely covered by the lower redistribution insulating layer 630. The plurality of lower UBM layers 640 may electrically connect the lower redistribution pattern 620 to an external connection terminal 900.

The external connection terminal 900 may be arranged on a lower surface of the lower redistribution structure 600. Some of the external connection terminals 900 may be arranged not to overlap the semiconductor package 10 in the vertical direction. The external connection terminal 900 may include, for example, solder. The external connection terminal 900 may physically and electrically connect between an external device and the semiconductor package 1000.

The semiconductor package 10 may be mounted on the lower redistribution structure 600. Because the semiconductor package 10 has been described above with reference to FIG. 1, a detailed description thereof is omitted.

The lower molding layer 710 may be arranged on the lower redistribution structure 600 and may cover at least a portion of the semiconductor package 10. The lower molding layer 710 may extend along the lower surface and opposing sidewalls of the semiconductor package 10 and may cover the lower surface and opposing sidewalls of the semiconductor package 10. An upper surface of the lower molding layer 710 may be coplanar with the upper surface of the semiconductor package 10. The upper surface of the lower molding layer 710 may be coplanar with an upper surface of the metal layer (refer to 440 in FIG. 1) of the semiconductor package 10. The lower molding layer 710 may include an insulating polymer or an epoxy resin. For example, the lower molding layer 710 may include EMC. In an embodiment, the lower molding layer 710 may include a material different from at least one material of the first molding layer (refer to 130 in FIG. 1) or the second molding layer (refer to 430 in FIG. 1) of the semiconductor package 10. For example, the lower molding layer 710 may include the same material as the first molding layer 230 but may include a different material from the second molding layer 430.

The lower connection structure 720 may be arranged on the lower redistribution structure 600 and may be connected to the lower redistribution pad 610 of the lower redistribution structure 600. The lower connection structure 720 may penetrate the lower molding layer 710 and may extend in the vertical direction.

The upper redistribution structure 800 may be arranged on the lower molding layer 710. The upper redistribution structure 800 may include an upper redistribution pattern 820 and an upper redistribution insulating layer 830.

The upper redistribution insulating layer 830 may cover the upper redistribution pattern 820. The upper redistribution insulating layer 830 may include a plurality of insulating layers stacked in the vertical direction or may include a single insulating layer. The upper redistribution insulating layer 830 may include, for example, PID or PSPI.

The upper redistribution pattern 820 may include a plurality of upper redistribution lines 823 extending in the horizontal direction and a plurality of upper redistribution vias 821 penetrating at least partially the upper redistribution insulating layer 830 and extending. The plurality of upper redistribution lines 823 may extend in the horizontal direction along at least one of an upper surface and a lower surface of each of the insulating layers constituting the upper redistribution insulating layer 830. Some of the plurality of upper redistribution lines 823 may be at a different vertical level from some of the rest of the plurality of upper redistribution lines 823. The plurality of upper redistribution vias 821 may electrically connect the plurality of upper redistribution lines 823 to each other at different vertical levels. In an embodiment, a horizontal width of the plurality of upper redistribution vias 821 may increase toward the semiconductor package 10.

In an embodiment, some of the plurality of upper redistribution vias 821 overlapping the semiconductor package 10 in the vertical direction may be in contact with the metal layer 440 of the semiconductor package 10.

In an embodiment, the remaining portions of the plurality of upper redistribution vias 821 which do not overlap the semiconductor package 10 in the vertical direction may be in contact with the lower connection structure 720. Accordingly, via the lower connection structure 720, the upper redistribution structure 800 may be electrically connected to the lower redistribution structure 600.

The upper redistribution pattern 820 may include a metal, such as Cu, Al, W, Ti, Ta, In, Mo, Mn, Co, Sn, Ni, Mg, Re, Be, Ga, Ru, and/or an alloy thereof. The upper redistribution pattern 820 may include a plurality of upper redistribution pads 810 at the uppermost end. Lower surfaces of a plurality of upper redistribution patterns 820 may be covered by the upper redistribution insulating layer 830.

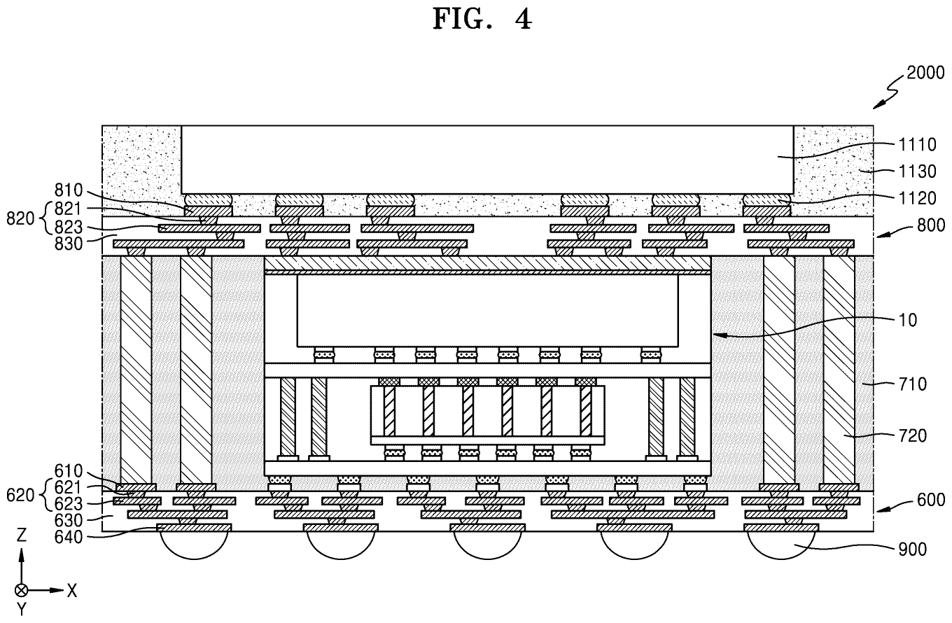

FIG. 4 is a cross-sectional view illustrating a semiconductor package 2000 according to an embodiment.

Referring to FIG. 4, the semiconductor package 2000 may include the lower redistribution structure 600, the semiconductor package 10, the lower molding layer 710, lower connection structures 720, the upper redistribution structure 800, an upper semiconductor chip 1110, and an upper molding layer 1130. Because the lower redistribution structure 600, the semiconductor package 10, the lower molding layer 710, the lower connection structures 720, and the upper redistribution structure 800 are similar to respective components of the semiconductor package 1000 described with reference to FIG. 3, the differences thereof are mainly described below.

The upper semiconductor chip 1110 may be arranged on the upper redistribution structure 800. In an embodiment, the upper semiconductor chip 1110 may include a memory chip or a logic chip. In an embodiment, the first semiconductor chip (refer to 210 in FIG. 1) and the second semiconductor chip (refer to 410 in FIG. 1) may include logic chips, and the upper semiconductor chip 1110 may include a memory chip. For example, the first semiconductor chip 210 and the second semiconductor chip 410 may include CPU chips, and the upper semiconductor chip 1110 may include DRAM chips. Although FIG. 4 illustrates that the semiconductor package 2000 includes one upper semiconductor chip 1110, the embodiment is not limited thereto, and the semiconductor package 2000 may include the plurality of upper semiconductor chips 1110.

An upper connection terminal 1120 may be arranged between the upper semiconductor chip 1110 and the upper redistribution structure 800. The upper connection terminal 1120 may physically and electrically connect the upper semiconductor chip 1110 to the upper redistribution structure 800.

The upper molding layer 1130 may cover at least a portion of the upper semiconductor chip 1110. The upper molding layer 1130 may extend along a lower surface and opposing sidewalls of the upper semiconductor chip 1110 and may cover the lower surface and opposing sidewalls of the upper semiconductor chip 1110. The upper surface of the upper molding layer 1130 may be coplanar with an upper surface of the upper semiconductor chip 1110. However, the embodiment is not limited thereto, and unlike as illustrated in FIG. 4, the upper molding layer 1130 may cover the upper surface of the upper semiconductor chip 1110. In an embodiment, the upper molding layer 1130 may include a material different from at least one material of the lower molding layer 710, the first molding layer 230, and the second molding layer 430. For example, the upper molding layer 1130 may include a material different from that of the second molding layer 430 and may include the same material as that of the first molding layer 230 and the lower molding layer 710.

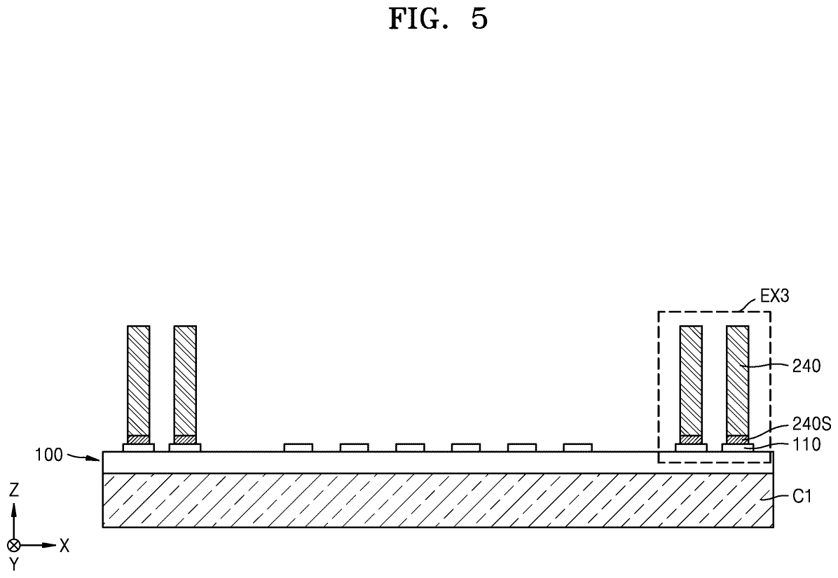

FIGS. 5, 6A, 6B, 6C, 6D, 7, 8, 9, 10, 11, and 12 are cross-sectional views of respective operations of a method of manufacturing a semiconductor package, according to embodiments. FIGS. 6A, 6B, 6C, and 6D are enlarged cross-sectional views describing the process in FIG. 5 in detail.

Referring to FIG. 5, a first carrier substrate C1 may be provided. The first carrier substrate C1 may include, for example, a semiconductor substrate, a glass substrate, a ceramic substrate, or a plastic substrate, but is not limited thereto. After the first carrier substrate C1 is provided, the first redistribution structure 100 may be formed on the first carrier substrate C1. In this case, the first redistribution insulating layer (refer to 130 in FIG. 2B) may be formed by using a lamination process, and the first redistribution pattern (refer to 120 FIG. 2B) may be formed by using a plating process. For example, operation of forming the first redistribution structure 100 may repeat processes of forming the first redistribution line 123, forming the first redistribution insulating layer 130 covering the first redistribution line 123, forming a via hole in the first redistribution insulating layer 130, and forming the first redistribution via 121 filling the via hole. After the first redistribution structure 100 is formed, the first connection structure 240 may be formed on the first redistribution structure 100. For example, the first connection structure 240 may be formed by forming the seed layer 240S and then by performing an electroplating process using the seed layer 240S.

FIGS. 6A, 6B, 6C, and 6D are enlarged cross-sectional views of region EX3 in FIG. 5, which describe in detail a process of forming the seed layer 240S on the first redistribution pad 110 and forming the first connection structure 240 from the seed layer 240S.

Referring to FIG. 6A, a first redistribution pad 110 may be formed on the first redistribution structure 100. The first redistribution pad 110 may include a structure in which an adhesive layer 112, a first pad layer 114, a second pad layer 116, and a third pad layer 118 are sequentially stacked.

In some embodiments, the first pad layer 114 may include Cu. In some embodiments, the second pad layer 116 may include Ni. In some embodiments, the third pad layer 118 may include Au. In some embodiments, the adhesive layer 112 may include a layer formed to stably connect the first, second, and third pad layers 114, 116, and 118 to the first redistribution structure 100. In some embodiments, a thickness of the first pad layer 114 in the vertical direction (Z direction) may be greater than those of the second pad layer 116 and the third pad layer 118.

Next, referring to FIG. 6B, a first preliminary seed layer 240S1′ having a conformal thickness that covers the side surface and the upper surface of the first redistribution pad 110 may be formed, and a second preliminary seed layer 240S2′ having a conformal thickness may be formed on the first preliminary seed layer 240S1′.

In some embodiments, the first preliminary seed layer 240S1′ may include Ti. In some embodiments, the second preliminary seed layer 240S2′ may include Cu.

Although FIG. 6B illustrates that the first preliminary seed layer 240S1′ and the second preliminary seed layer 240S2′ are deposited to have the same thickness, this is only an example, and the first and second preliminary seed layers 240S1′ and 240S2′ may have different thicknesses from each other.

Referring to FIG. 6C, a preliminary first connection structure 240′may be formed on the second preliminary seed layer 240S2′. In some embodiments, the preliminary first connection structure 240′may include Cu.

Next, a Czochralski (CZ) process may be performed on the preliminary first connection structure 240′. In this case, the CZ process may include a process of growing Cu included in the preliminary first connection structure 240′into single crystal copper.

After the CZ process is performed, the preliminary first connection structure 240′may become the first connection structure (refer to 240 in FIG. 6D), and roughness may be formed on one or more surfaces of the first connection structure 240. In some embodiments, the surface roughness of the first connection structure 240 may range from about 0.07 μm to about 0.3 μm. For example, the absolute value of the distance between the deepest valley and the highest peak over the surface of the first connection structure 240 on which the roughness may be formed may range from about 0.07 μm to about 0.3 μm. As another example, the first connection structure 240 may have an average roughness depth of about 0.07 μm to 0.3 μm. For example, the surface roughness of the first connection structure 240 may be about 0.2 μm. The surface roughness may be formed on the first connection structure 240 to prevent peeling in advance that may occur between the first molding layer (refer to 230 in FIG. 1) and the first connection structure 240 down the line in subsequent processes.

Because the first and second preliminary seed layers 240S1′ and 240S2′ surround up to the entire surface (e.g., the upper and side surfaces) of the first redistribution pad 110, by preventing the occurrence of galvanic corrosion in which unnecessary roughness is formed on the first redistribution pad 110 during the CZ process, the inventive concept may secure the mechanical stability of the semiconductor packages 10, 1000, and 2000.

Referring to FIG. 6D, by etching portions of the first and second preliminary seed layers 240S1′ and 240S2′, the seed layer 240S may be formed. The seed layer 240S may include a first seed layer 240S1 and a second seed layer 240S2. The seed layer 240S may, as illustrated in FIG. 6D, be arranged between the first redistribution pad 110 and the first connection structure 240, a horizontal cross-sectional area of the seed layer 240S may be less than that of the first redistribution pad 110 and may be the same as that of the first connection structure 240.

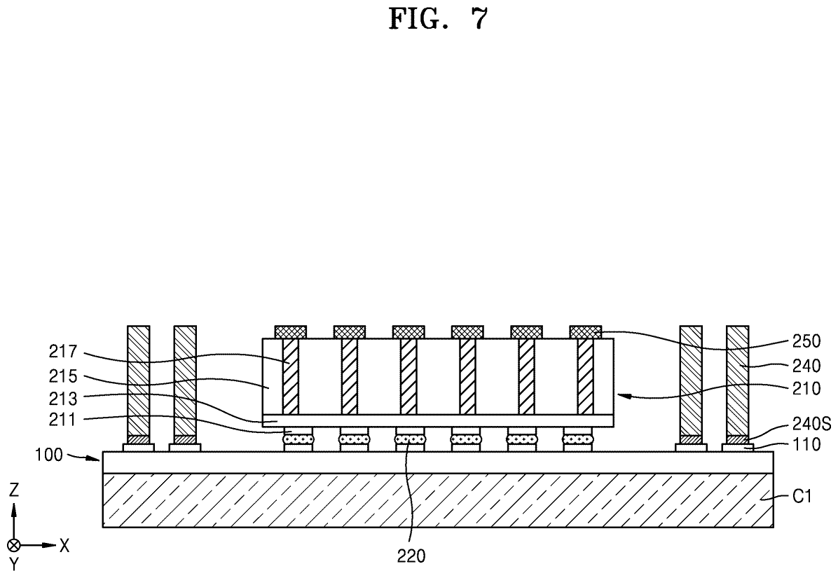

Referring to FIG. 7, in the resultant product of FIG. 5, the first semiconductor chip 210 including the wiring structure 213 and the through electrode 217 on the first redistribution structure 100, and the second connection structure 250 on the upper surface of the first redistribution structure 100 may be mounted. The first semiconductor chip 210 may be mounted on the first redistribution structure 100 via the first connection terminal 220. As the first connection terminal 220 is coupled to the first redistribution pad 110 and the first chip pad 211, the first semiconductor chip 210 may be fixed on the first redistribution structure 100. In this case, the first semiconductor chip 210 may be mounted such that the first inactive surface 215Sb of the first semiconductor chip 210 faces the first redistribution structure 100.

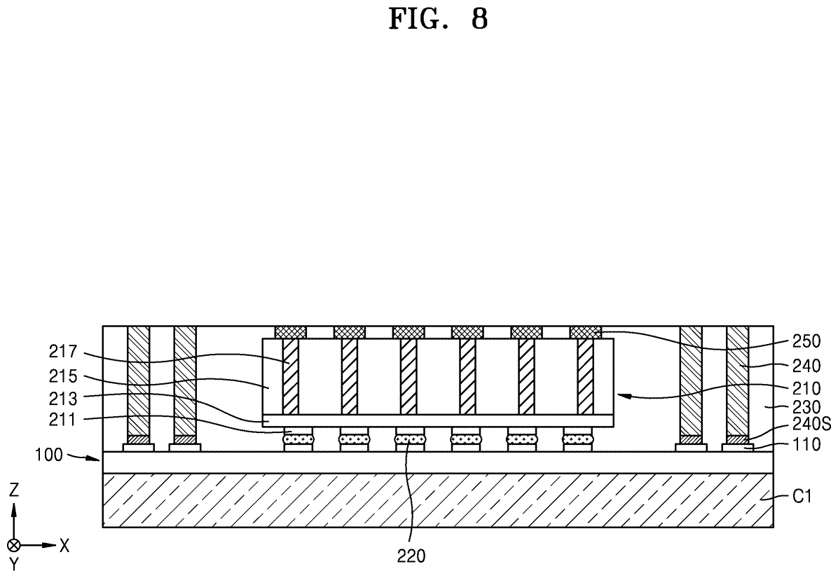

Referring to FIG. 8, from the resultant product of FIG. 7, the first molding layer 230 may be formed on the first redistribution structure 100. In this case, the first molding layer 230 may cover the upper surface, the lower surface, and opposing sidewalls of the first semiconductor chip 210. After the first molding layer 230 is formed, a planarization process may be performed on the first molding layer 230. As the planarization process is performed, the upper surface of the first molding layer 230 may be coplanar with the upper surface of the first connection structure 240 and the upper surface of the second connection structure 250.

Because a CZ process of forming the surface roughness is performed on the first connection structure 240 (refer to FIGS. 6A through 6D), peeling between the first connection structure 240 and the first molding layer 230 may be prevented.

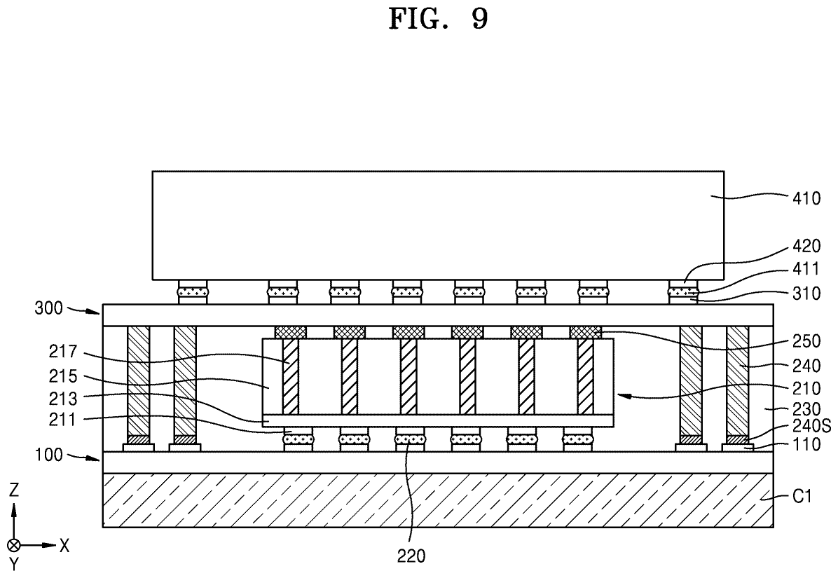

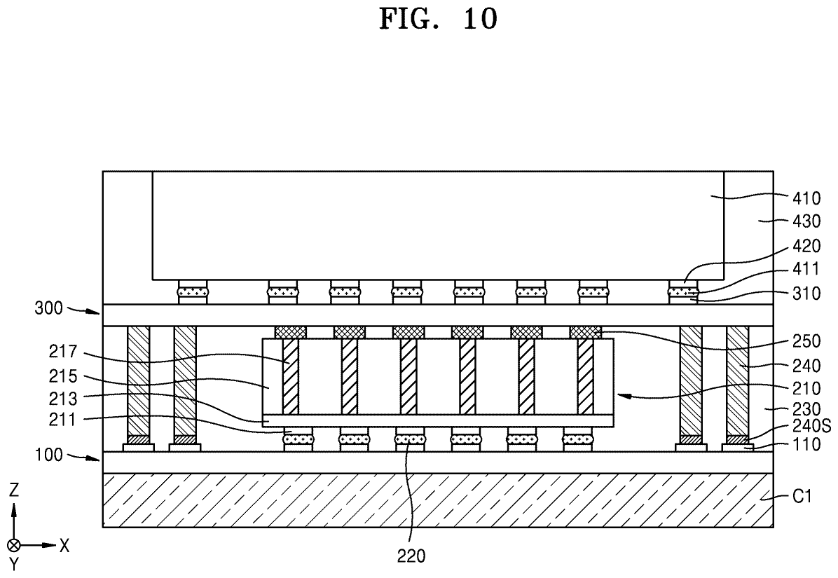

Referring to FIG. 9, a second redistribution structure 300 may be formed on the first molding layer 230 on which the planarization process has been performed. The second redistribution structure 300 may be formed in the same method as the method of forming the first redistribution structure 100 described with reference to FIG. 5. After the second redistribution structure 300 is formed, the second semiconductor chip 410 may be mounted on the second redistribution structure 300. The second semiconductor chip 410 may be mounted on the second redistribution structure 300 via the second connection terminal 411. As the second connection terminal 411 is bonded to the second redistribution pad 310 and the second chip pad 420, the second semiconductor chip 410 may be fixed on the second redistribution structure 300. In this case, the second semiconductor chip 410 may be mounted such that the second active surface 413Sa of the second semiconductor chip 410 faces the second redistribution structure 300.

Referring to FIG. 10, from the resultant product of FIG. 9, the second molding layer 430 may be formed on the second redistribution structure 300. In this case, the second molding layer 430 may cover a lower surface and opposing sidewalls of a second semiconductor chip 410. After the second molding layer 430 is formed, a planarization process may be performed on the second molding layer 430. As the planarization process is performed, the upper surface of the second molding layer 430 may be coplanar with the upper surface of the second semiconductor chip 410. Because the second molding layer 430 is formed by using a separate process from the first molding layer 230, the first molding layer 230 and the second molding layer 430 may include different materials, but the embodiment is not limited thereto.

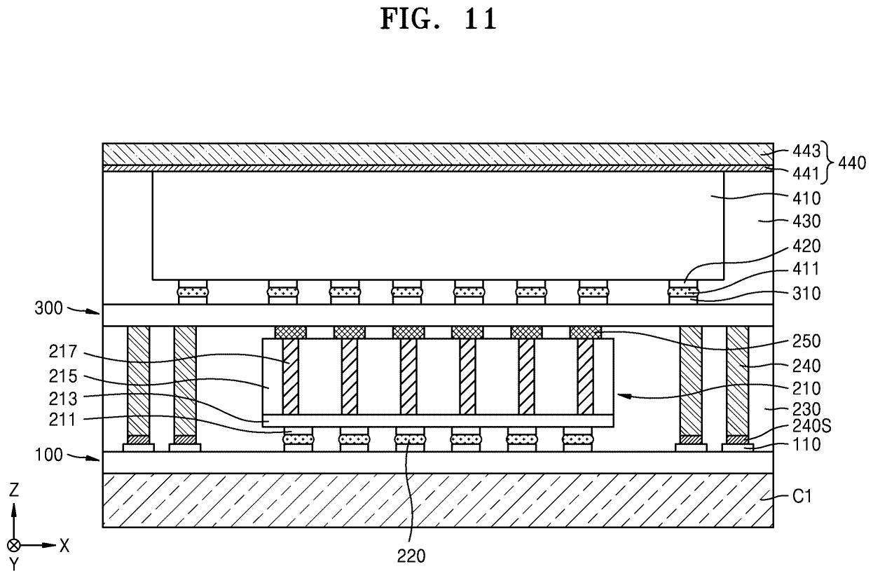

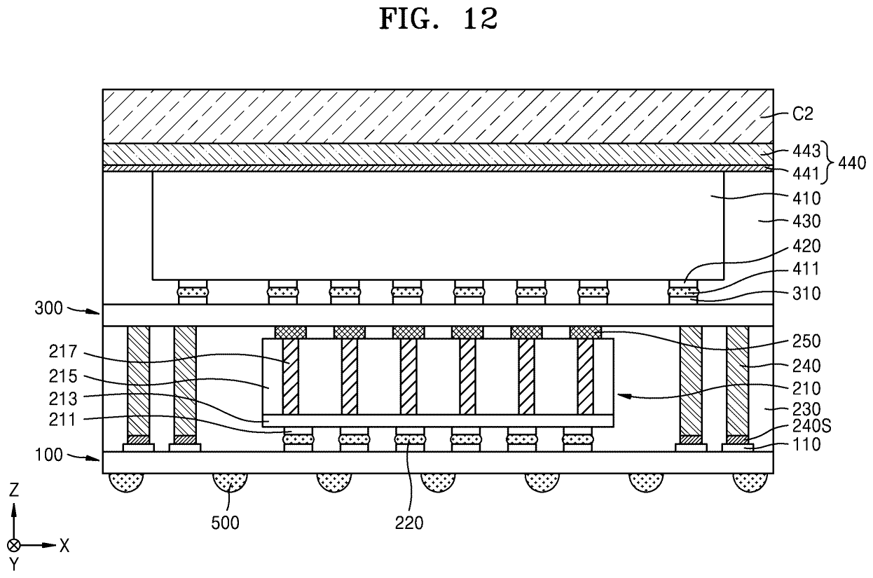

Referring to FIG. 11, from the resultant product of FIG. 10, the metal layer 440 may be formed on the second semiconductor chip 410 and the second molding layer 430. After the first metal layer 441 is formed on the second semiconductor chip 410 and the second molding layer 430, the second metal layer 443 may be formed on the first metal layer 441. The first metal layer 441 may be formed by using a deposition process, for example, a physical vapor deposition (PVD) process. The second metal layer 443 may be formed by forming a seed layer on the first metal layer 441 by using a deposition process, and by performing an electroplating process on the seed layer. In an embodiment, the first metal layer 441 may include Ti, and the second metal layer 443 may include Cu. In an embodiment, the metal layer 440 may be formed to completely cover an upper surface of the second semiconductor chip 410 and the upper surface of the second molding layer 430.

Referring to FIG. 12, from the resultant product of FIG. 11, a second carrier substrate C2 may be attached onto an upper surface of the metal layer 440. The second carrier substrate C2 may be substantially the same as or similar to the first carrier substrate C1. After the second carrier substrate C2 is attached, the first carrier substrate C1 may be removed from the lower surface of the first redistribution structure 100. After the first carrier substrate C1 is removed, the external connection terminal 500 may be formed on the lower surface of the first redistribution structure 100.

Thereafter, as the second carrier substrate C2 is removed from the resultant product of FIG. 12, the semiconductor package 10 illustrated in FIG. 1 may be manufactured.

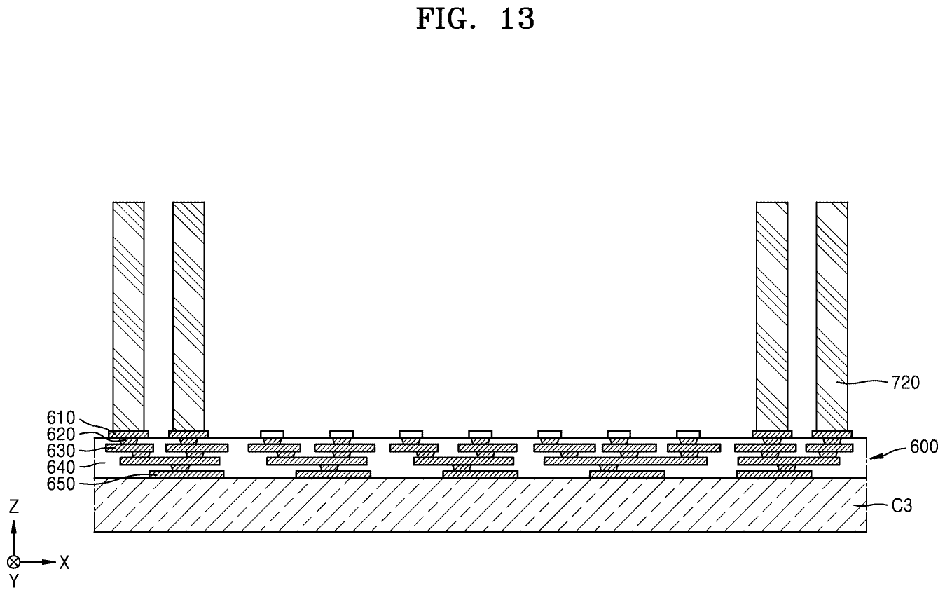

FIGS. 13 through 16 are cross-sectional views illustrating respective operations of the method of manufacturing the semiconductor package 1000, according to embodiments.

Referring to FIG. 13, a third carrier substrate C3 may be provided. The third carrier substrate C3 may be the same as or similar to the first carrier substrate C1. After the third carrier substrate C3 is provided, the lower redistribution structure 600 may be formed on the third carrier substrate C3. The lower redistribution structure 600 may be formed in the same method as the method of forming the first redistribution structure 100 described with reference to FIG. 5. After the lower redistribution structure 600 is formed, the lower connection structure 720 may be formed on the lower redistribution structure 600. The lower connection structure 720 may be formed in the same manner as the method of forming the first connection structure 240 described with reference to FIG. 5.

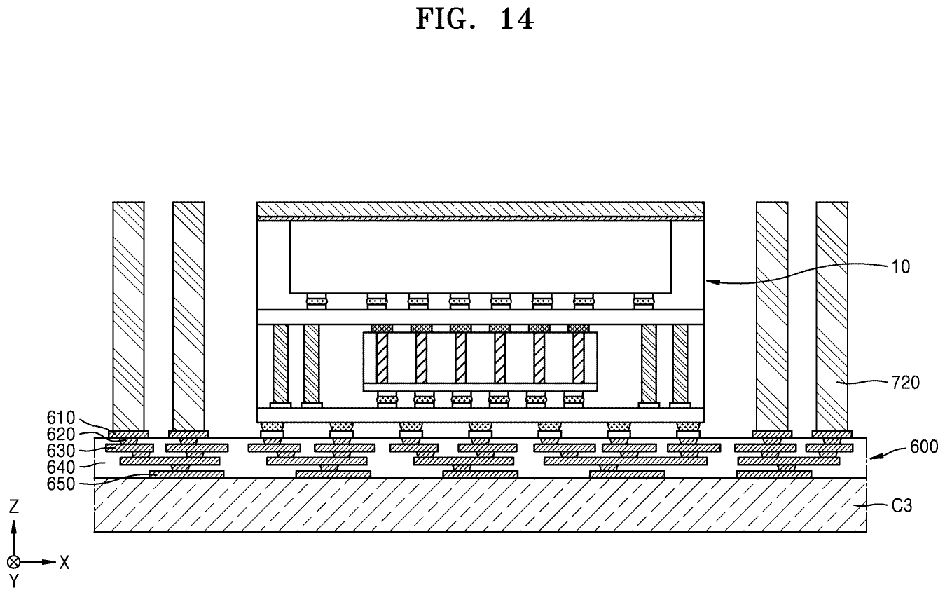

Referring to FIG. 14, onto the resultant product of FIG. 13, the semiconductor package 10 may be mounted. The semiconductor package 10 may be mounted on the lower redistribution structure 600 via an external connection terminal refer to 500 in FIG. 1). As the external connection terminal 500 is bonded to the lower redistribution pad 610 and the UBM layer (refer to 140 in FIG. 1), the semiconductor package 10 may be fixed on the lower redistribution structure 600.

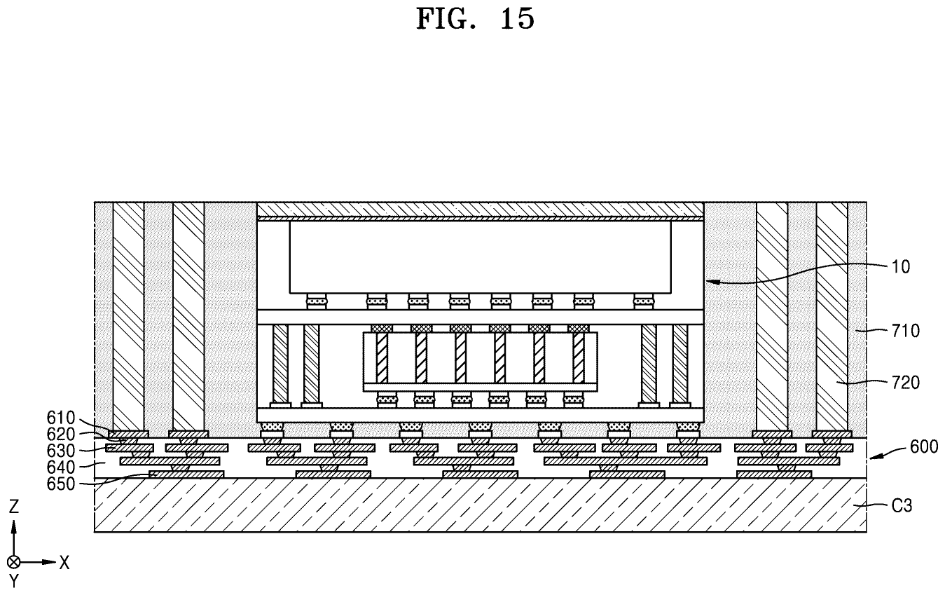

Referring to FIG. 15, from the resultant product of FIG. 14, the lower molding layer 710 may be formed on the lower redistribution structure 600. In this case, the lower molding layer 710 may cover the lower surface and opposing sidewalls of the semiconductor package 10. After the lower molding layer 710 is formed, a planarization process may be performed on the lower molding layer 710. As the planarization process is performed, an upper surface of the lower molding layer 710 may be coplanar with the upper surface of the semiconductor package 10. In an embodiment, the lower molding layer 710 may include a material different from at least one material of the first molding layer (refer to 230 in FIG. 1) and the second molding layer (refer to 430 in FIG. 1).

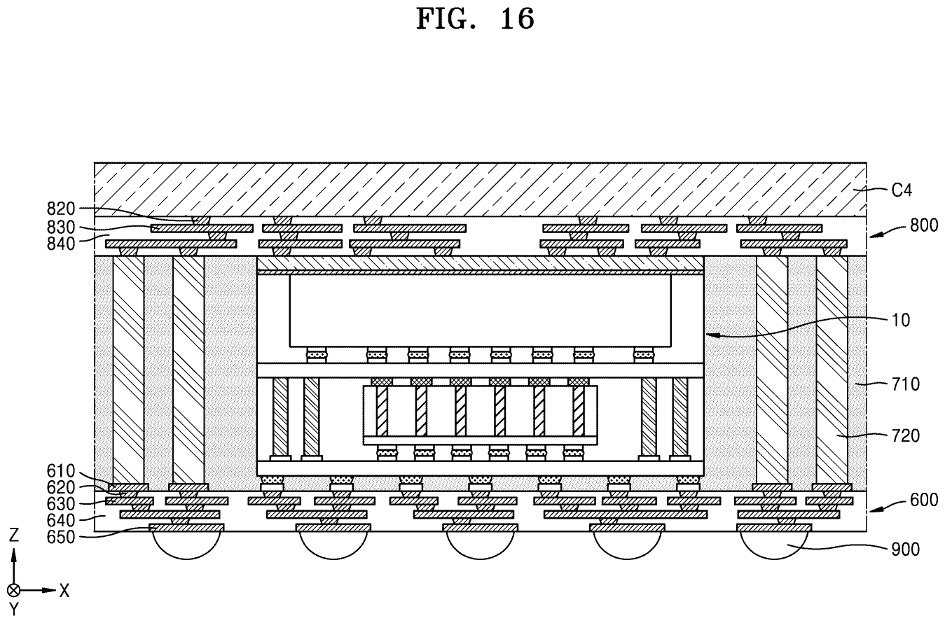

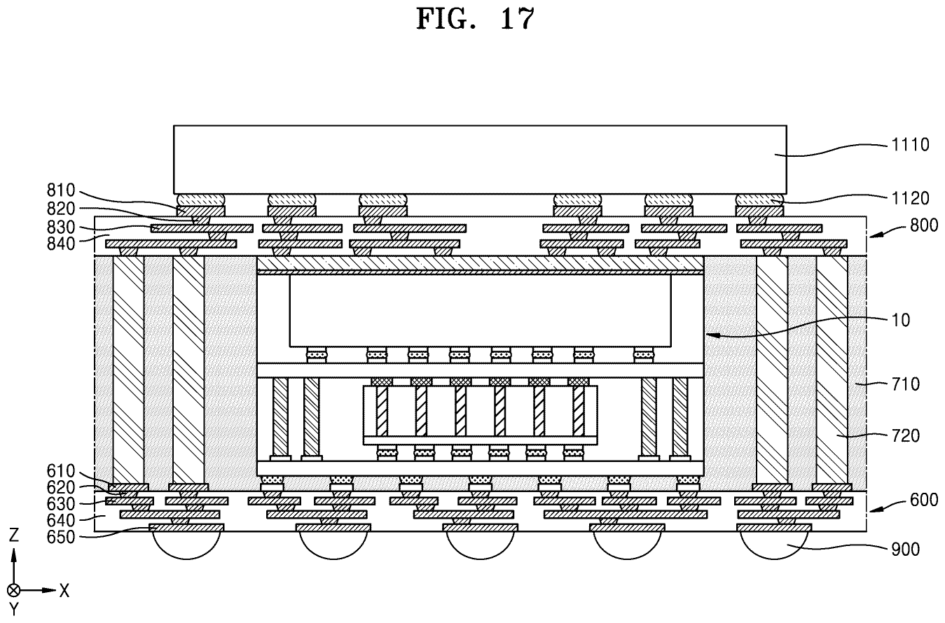

Referring to FIG. 16, from the resultant product of FIG. 15, the upper redistribution structure 800 may be formed on the semiconductor package 10 and the lower molding layer 710. The upper redistribution structure 800 may be formed in the same manner as the method of forming the first redistribution structure 100 described with reference to FIG. 5. After the upper redistribution structure 800 is formed, a fourth carrier substrate C4 may be attached onto the upper redistribution structure 800. The fourth carrier substrate C4 may be substantially the same as or similar to the first carrier substrate C1. After the fourth carrier substrate C4 is attached onto the upper redistribution structure 800, the third carrier substrate C3 may be removed from the lower surface of the lower redistribution structure 600, and the external connection terminal 900 may be formed on the lower surface of the lower redistribution structure 600.

Thereafter, from the resultant product of FIG. 16, the fourth carrier substrate C4 may be removed, and an upper redistribution pad 810 may be formed, and thus the semiconductor package 1000 illustrated in FIG. 3 may be manufactured.

FIG. 17 is a cross-sectional view of a method of manufacturing the semiconductor package 2000, according to an embodiment.

Referring to FIG. 17, after the fourth carrier substrate C4 is removed from the resultant product of FIG. 16 to manufacture the semiconductor package 1000 illustrated in FIG. 3, the upper semiconductor chip 1110 may be mounted on the upper redistribution structure 800. The upper semiconductor chip 1110 may be mounted on the upper redistribution structure 800 via the upper connection terminal 1120. Accordingly, the upper semiconductor chip 1110 may be fixed on the upper redistribution structure 800.

Thereafter, from the resultant product of FIG. 17, the upper molding layer 1130 may be formed on the upper redistribution structure 800. In this case, the upper molding layer 1130 may cover the lower surface and opposing sidewalls of the upper semiconductor chip 1110. However, the embodiment is not limited thereto, and the upper molding layer 1130 may also cover the upper surface, the lower surface, and opposing sidewalls of the upper semiconductor chip 1110. As a result of forming the upper molding layer 1130, the semiconductor package 2000 illustrated in FIG. 4 may be manufactured.

While the inventive concept has been particularly shown and described with reference to embodiments thereof, it will be understood that various change in form and details may be made therein without departing from the scope of the following claims.

What is claimed is:

1. A method of manufacturing a semiconductor package, the method comprising:
forming a plurality of redistribution pads comprising forming a first pad layer, a second pad layer, and a third pad layer sequentially stacked on a redistribution structure;
forming a preliminary seed layer conformally extending on an upper surface of the redistribution structure, and on upper surfaces and side surfaces of the plurality of redistribution pads;
forming a metal pillar on the preliminary seed layer;
forming surface roughness on the metal pillar; and
etching at least a portion of the preliminary seed layer exposed on the side surfaces of the plurality of redistribution pads and the upper surface of the redistribution structure to provide a seed layer between the metal pillar and one of the plurality of redistribution pads thereon.

2. The method of claim 1, wherein the seed layer comprises a first seed layer and a second seed layer on the first seed layer.

3. The method of claim 2, wherein the first seed layer comprises titanium (Ti), and the second seed layer comprises copper (Cu).

4. The method of claim 1, wherein the metal pillar comprises Cu.

5. The method of claim 1, wherein the forming surface roughness on the metal pillar is performed by a Czochralski (CZ) process.

6. The method of claim 1, wherein the surface roughness of the metal pillar is in a range of about 0.07 micrometers (μm) to about 0.3 μm.

7. The method of claim 1, wherein the forming of the surface roughness on the metal pillar is limited to side surfaces of the metal pillar.

8. The method of claim 1, wherein, during the forming of the surface roughness on the metal pillar, the plurality of redistribution pads are protected by the preliminary seed layer such that, responsive to the forming of the surface roughness on the metal pillar, roughness is not formed on the plurality of redistribution pads.

9. The method of claim 1, wherein the etching the at least a portion of the preliminary seed layer exposes at least a portion of an upper surface of the third pad layer.

10. The method of claim 1, wherein the seed layer is formed to overlap the metal pillar in a plan view.

11. The method of claim 1, wherein the first pad layer comprises copper (Cu), the second pad layer comprises nickel (Ni), and the third pad layer comprises gold (Au).

12. The method of claim 1, wherein a thickness of the first pad layer is greater than a thickness of the second pad layer and a thickness of the third pad layer.

13. The method of claim 1, wherein each of the plurality of redistribution pads further comprise an adhesive layer between the redistribution structure and the first pad layer.

14. The method of claim 1, further comprising:
forming a molding layer covering exposed surfaces of the redistribution structure, the plurality of redistribution pads, the seed layer, and the metal pillar.

15. A method of manufacturing a semiconductor package, the method comprising:
forming a plurality of redistribution pads on a redistribution structure;
forming a preliminary seed layer conformally extending on an upper surface of the redistribution structure, and on upper surfaces and side surfaces of the redistribution pads;
forming metal pillars on the preliminary seed layer, the metal pillars having respective cross-sectional areas less than those of the plurality of redistribution pads;
forming surface roughness on side surfaces of the metal pillars; and
providing a plurality of seed layers between the plurality of redistribution pads and the metal pillars, by etching the preliminary seed layer to expose the upper surface of the redistribution structure and a portion of the upper surface and side surfaces of the plurality of redistribution pads,
wherein the plurality of redistribution pads comprise copper (Cu), nickel (Ni), and gold (Au) sequentially stacked between the redistribution structure and an adhesive layer, and the plurality of seed layers comprise titanium (Ti) and Cu sequentially stacked.

16. The method of claim 15, wherein the forming of the surface roughness on the side surfaces of the metal pillars is performed by a Czochralski (CZ) process.

17. The method of claim 15, wherein the surface roughness of the side surfaces of the metal pillars is in a range of about 0.07 micrometers (μm) to about 0.3 μm.

18. The method of claim 15, wherein, during the forming of the surface roughness on the metal pillars, the plurality of redistribution pads are protected by the preliminary seed layer such that, responsive to the forming of the surface roughness on the metal pillars, roughness is not formed on the plurality of redistribution pads.

19. The method of claim 15, wherein the metal pillars comprise Cu.

20. A method of manufacturing a semiconductor package, the method comprising:
forming a plurality of redistribution pads respectively comprising copper (Cu), nickel (Ni), and gold (Au) sequentially stacked on a redistribution structure comprising a redistribution via and a redistribution line;
forming a preliminary seed layer conformally extending on an upper surface of the redistribution structure, and on upper surfaces and side surfaces of the plurality of redistribution pads, the preliminary seed layer comprising a first layer comprising titanium (Ti) and a second layer comprising copper (Cu) sequentially stacked;
forming a metal pillar having a cross-sectional area less than those of the plurality of redistribution pads on the preliminary seed layer;
performing a Czochralski (CZ) process on the metal pillar;
removing portions of the preliminary seed layer such that a portion thereof remains between one of the plurality of redistribution pads and the metal pillar as a seed layer;
mounting at least one semiconductor chip on the redistribution structure; and
forming a molding layer in a space between the at least one semiconductor chip and the metal pillar.
